(19) United States
(12) Patent Application Publication
(10) Pub. No.: US 2026/0110742 A1
(43) Pub. Date: Apr. 23, 2026

(54) TRANSFER LEARNING BASED BATTERY STATE OF POWER ESTIMATION TECHNIQUES WITH UPDATING THROUGH BATTERY LIFETIME

(71) Applicants: FCA US LLC, Auburn Hills, MI (US); McMaster University, Hamilton (CA)

(72) Inventors: Junran Chen, Hamilton (CA); Satyam Panchal, Auburn Hills, MI (US); Oliver Gross, Auburn Hills, MI (US); Dipan Arora, Auburn Hills, MI (US); Phillip Kollmeyer, Hamilton (CA); Qi Yao, Hamilton (CA); Yasaman Masoudi, Auburn Hills, MI (US); Carlos Jose Gonclaves Vidal, Hamilton (CA); Mina Gamal Maguib Nassim, Hamilton (CA)

(21) Appl. No.: 19/239,250

(22) Filed: Jun. 16, 2025

Related U.S. Application Data
(63) Continuation-in-part of application No. 18/919,001, filed on Oct. 17, 2024.

(51) Int. Cl. G01R 31/367; G01R 31/3842; G01R 31/392

(52) U.S. Cl. CPC G01R 31/367; G01R 31/3842; G01R 31/392

(57) ABSTRACT

Update systems and methods for a trained state of power (SOP) estimation model for a battery system of an electrified vehicle include obtaining real-time operation data of the battery system while deployed in the electrified vehicle, accessing the SOP estimation model, wherein the SOP estimation model is a machine learning model that is configured to estimate a SOP of the battery system based on a set of input parameters, identifying and obtaining, from a database configured to store lab data including test data of the battery system across a plurality of different operation conditions, a subset of the lab data that is most relevant to the real-time operation data of the battery system, updating the SOP estimation model via a low learning rate transfer learning process and using at least the subset of the lab data to obtain an updated SOP estimation model, and outputting the updated SOP estimation model.

### CROSS-REFERENCE TO RELATED APPLICATION(S)

The present application is a continuation-in-part (CIP) of U.S. patent application Ser. No. 18/919,001, filed on Oct. 17, 2024. The disclose of this application is incorporated herein by reference in its entirety.

### FIELD

The present application generally relates to electrified vehicles and, more particularly, to techniques for estimating battery system power capability using machine learning models and search algorithms.

### BACKGROUND

An electrified vehicle includes a high voltage battery system configured to output electrical energy (i.e., current and voltage) to power one or more electric motors, such as for vehicle propulsion. State of power (SOP) is a metric of a battery system that represents a maximum amount of power that the battery system can absorb or release for a specific length of time. Battery system SOP is thus a critical metric for high power applications such as electrified vehicles. If the battery system SOP is over-estimated, it could result in a system malfunction due to safe operating limits being exceeded and, in extreme cases, could potentially result in reduced battery life, thermal runaway, and/or other damage (e.g., overloading) and thereby increased replacement or warranty costs. If the battery system SOP is underestimated, the battery power will be unnecessarily limited and negatively impact performance (response, vehicle range, etc.). While conventional battery system SOP estimation techniques do work for their intended purpose, there exists an opportunity for improvement in the relevant art.

### SUMMARY

According to one example aspect of the invention, a state of power (SOP) estimation system for an electrified vehicle is presented. In one exemplary implementation, the SOP estimation system comprises a battery system of the electrified vehicle and a control system configured to access a trained battery voltage estimation model configured to estimate a voltage of the battery system based on a set of input parameters including at least state of charge (SOC), temperature, and power or current, perform a search process to determine a final estimated SOP that causes the estimated voltage of the battery system to fall within a desired voltage range, and control the electrified vehicle based on the final estimated SOP of the battery system.

In some implementations, the trained battery voltage estimation model is a long short-term memory (LSTM) based recurrent neural network model. In some implementations, the search process is a binary search process. In some implementations, the trained battery voltage estimation model is obtained by training a battery voltage estimation model using a sequence training process. In some implementations, the trained battery voltage estimation model includes two hidden LSTM layers each having sixteen hidden units.

In some implementations, the search process is a binary search process. In some implementations, the trained battery voltage estimation model is obtained by training a battery voltage estimation model using a sequence training process. In some implementations, the training using the sequence training process enables the battery voltage estimation model to be trained from a discontinuous dataset, which thereby increases an accuracy of the battery voltage estimation model.

In some implementations, the search process includes, for each iteration: applying a different power pulse to the trained battery voltage estimation model to determine an estimated voltage of the battery system, determine whether the estimated voltage of the battery system falls within the desired voltage range corresponding to an acceptable error tolerance, and when the estimated voltage of the battery system does not fall within the desired voltage range, increasing or decreasing the power pulse for a next iteration. In some implementations, the control system is not configured to utilize, for SOP estimation of the battery system, either (i) a characteristic mapping method or (ii) an equivalent circuit model (ECM) or electrochemical model for the battery system.

According to another example aspect of the invention, an SOP estimation method for an electrified vehicle is presented. In one exemplary implementation, the SOP estimation method comprises accessing, by a control system of the electrified vehicle, a trained battery voltage estimation model configured to estimate a voltage of a battery system of the electrified vehicle based on a set on input parameters including at least SOC, temperature, and power or current, performing, by the control system, a search process to determine a final estimated SOP that causes the estimated voltage of the battery system to fall within a desired voltage range, and controlling, by the control system, the electrified vehicle based on the final estimated SOP of the battery system.

In some implementations, the trained battery voltage estimation model is an LSTM-based recurrent neural network model. In some implementations, the search process is a binary search process. In some implementations, the trained battery voltage estimation model is obtained by training a battery voltage estimation model using a sequence training process. In some implementations, trained battery voltage estimation model includes two hidden LSTM layers each having sixteen hidden units.

In some implementations, the search process is a binary search process. In some implementations, the trained battery voltage estimation model is obtained by training a battery voltage estimation model using a sequence training process. In some implementations, the training using the sequence training process enables the battery voltage estimation model to be trained from a discontinuous dataset, which thereby increases an accuracy of the battery voltage estimation model.

In some implementations, the search process includes, for each iteration: applying a different power pulse to the trained battery voltage estimation model to determine an estimated voltage of the battery system, determine whether the estimated voltage of the battery system falls within the desired voltage range corresponding to an acceptable error tolerance, and when the estimated voltage of the battery system does not fall within the desired voltage range, increasing or decreasing the power pulse for a next iteration. In some implementations, the control system is not configured to utilize, for SOP estimation of the battery system, either (i) a characteristic mapping method or (ii) an ECM or electrochemical model for the battery system.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 illustrates a functional block diagram of an electrified vehicle having an example battery state of power (SOP) estimation system according to the principles of the present application;

FIG. 2 illustrates a functional block diagram of an example structure of a long short-term memory (LSTM) battery voltage estimation model according to the principles of the present application;

FIGS. 3A-3B illustrate example trainings of the LSTM battery voltage estimation model using continuous data and sequence data according to the principles of the present application;

FIG. 4 illustrates a flow diagram of an example SOP estimation method for an electrified vehicle including a binary search process according to the principles of the present application;

FIG. 5 illustrates example iterations of the binary search process of for the example SOP estimation method of FIG. 4 according to the principles of the present application;

FIG. 6 illustrates example LSTM model data and state flow during an example SOP estimation process according to the principles of the present application;

FIG. 7 illustrates a plot showing a comparison between estimated and measured ten-second discharging SOP at six different temperatures according to the principles of the present application;

FIG. 8 illustrates a functional block diagram of an example update system for a trained SOP estimation model for a battery system of an electrified vehicle according to the principles of the present application;

FIGS. 9A-9B illustrate plots of example SOP estimation modeling for a battery system of an electrified vehicle at different discharge capacities and temperatures according to the principles of the present application;

FIGS. 10A-10C illustrate plots of various steps of an example update method for a trained SOP estimation model for a battery system of an electrified vehicle according to the principles of the present application;

FIGS. 11A-11C illustrate comparative plots of example operation data compared to lab data for a battery system of an electrified vehicle according to the principles of the present application;

FIGS. 12A-12D illustrate plots of example SOP measurement test results versus state of charge (SOC) and 1C charge profiles after various aging cycles according to the principles of the present application; and

FIGS. 13A-13D illustrate plots of example SOP estimation accuracy improvements between an original/trained and retrained/updated SOP estimation model according to the principles of the present application.

### DESCRIPTION

As previously discussed, battery system state of power (SOP) is a critical metric for high power applications such as electrified vehicles. If the battery system SOP is over-estimated, it could result in a system malfunction due to safe operating limits being exceeded and, in extreme cases, could potentially result in reduced battery life, thermal runaway, and/or other damage (e.g., overloading) and thereby increased replacement or warranty costs. If the battery SOP is underestimated, the battery power will be unnecessarily limited and negatively impact performance (response, vehicle range, etc.). Unfortunately, battery system SOP cannot be measured directly using sensors like other parameters (current, voltage, temperature, etc.). Thus, a battery model-based algorithm is required to estimate SOP during battery system operation. Conventional methods rely on equivalent circuit models or electrochemical models, which require in-depth knowledge and characterization test data for precise modeling and still may not achieve satisfactory accuracy. These conventional SOP estimation techniques will now be discussed in greater detail.

The most straightforward SOP estimation algorithm is characteristic mapping developed from a battery characterization test. Characteristic mapping states the relation between battery SOC, voltage, temperature, power pulse duration, and power capability. This map is stored in the BMS and called every time step during battery operation. A typical method to generate this map is the hybrid pulse power characterization (HPPC) test. More advanced SOP estimation approaches are based on dynamic battery models, and the most common approaches among them are battery equivalent circuit model (ECM) based methods. Based on the open circuit voltage resistance (OCV-R) battery model, direct SOP estimation methods provide a fast and accurate estimation of maximum power considering operational-related constraints. In cases where the power pulse duration is short (e.g., 1 second), a simple OCV-R model is typically sufficient for SOP estimation since the longer term dynamics of the battery do not have an impact over this brief period. However, for power pulses of greater length, accurate predictions become challenging due to the time-dependent, nonlinear dynamics of lithium-ion batteries. Therefore, equivalent circuit models (ECMs) with one or more resistor capacitor (RC) pairs and current-dependent resistance values, are applied with iterative algorithms to predict the SOP. For potentially higher estimation accuracy and a more in-depth understanding of the internal electrochemical processes, electrochemical models are applied to estimate battery SOP at the cost of higher computing power.

While the characteristic mapping method is straightforward to implement, it has limitations that impact the accuracy of SOP prediction. Firstly, it ignores the effect of various electrochemical processes, which can lead to low accuracy. Additionally, it requires a significant amount of memory storage to maintain extensive battery state information to ensure accuracy. Furthermore, addressing the uncertainty of parameters arising from battery degradation is challenging, resulting in a gradual decline in SOP estimation accuracy over years of usage. Conventional SOP estimation methods based on dynamic battery models, such as ECMs or electrochemical models, incorporate battery chemical processes, including polarization and resistance hysteresis. This incorporation theoretically results in higher estimation accuracy than the characteristic mapping method. However, both ECM-based and electrochemical model-based SOP estimation methods have their limitations. For the ECM-based method, it cannot provide detailed physical insight into the internal electrochemical processes, which can be vital for accurately estimating SOP. The electrochemical model-based method covers the dynamics of internal electrochemical states, e.g., electrode surface concentration, electrolyte concentration, and side-reaction over-potential. It thus offers massive potential in ensuring accurate SOP estimation. However, implementing such a complex model in real-time applications remains challenging without additional techniques to enhance efficiency.

Accordingly, improved machine-learning based battery system SOP estimation techniques are presented herein. These techniques utilize a machine learning-based battery modeling technique and binary searching for SOP estimation. The techniques can be generally divided into two parts: (1) a long short-term memory (LSTM) network-based battery voltage estimation model, whose inputs include measured SOC, temperature, and power, and may include different inputs if needed, and (2) a binary search process to determine battery SOP from the model. While an LSTM network based model is proposed herein, it will be appreciated that another suitable neural network based model could also be utilized. Additionally, there are numerous alternatives to the binary search algorithm described herein, which can be utilized to determine SOP from the model. The LSTM network based model provides various benefits, which are discussed in greater detail herein. Potential benefits of the battery system SOP estimation techniques of the present application include more accurate SOP estimation (e.g., compared to the conventional SOP estimation techniques described above) and thus improved electrified vehicle performance (response, range, etc.) and avoiding the other above-described drawbacks of inaccurate SOP estimation (i.e., under-estimation and overestimation).

A key innovation of the proposed techniques is substituting the battery voltage estimation model's input parameter from current, the more conventional approach, to power. This alteration eliminates the need for an additional iteration loop to calculate the battery current needed to achieve the power command at each time step, thereby reducing computation requirements by a factor of five or more. The accuracy of this algorithm could not have been achieved without the presented sequence training method, whose application to battery voltage estimation is a new contribution as well. Additionally, a novel battery SOP binary search process is proposed. This process iteratively searches SOP by applying virtual power pulses to the battery model and updating next-step power according to the model response. Other conventional techniques employ constant current pulses instead of constant power pulses to battery models virtually and subsequently calculate battery SOP by multiplying the calculated maximum current by the estimated average or end-time voltage. However, such an approach can introduce errors in the estimation since SOP is defined on constant power pulses.

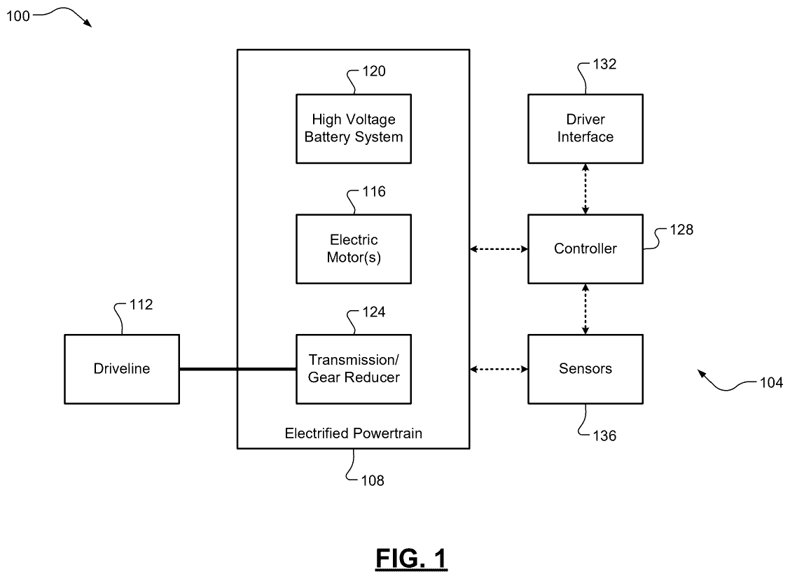

Referring now to FIG. 1, a functional block diagram of an electrified vehicle 100 having an example battery SOP estimation system 104 (e.g., a computing device plus sensors) according to the principles of the present application is illustrated. The electrified vehicle 100 (also “vehicle 100”) generally comprises an electrified powertrain 108 configured to generate and transfer drive torque to a driveline 112 for vehicle propulsion. The electrified powertrain 108 includes, for example, one or more electric motors 116 (e.g., a three-phase traction motor) configured to generate drive torque using electrical energy (current) provided by a high voltage battery pack or system 120. The drive torque is transferred from the electric motor(s) 116 to the driveline 112 via a transmission or gear reducer 124. It will be appreciated that the electrified powertrain 108 could include other non-illustrated components, such as an internal combustion engine configured to combust a fuel/air mixture to generate mechanical energy, which could be used for propulsion and/or converted to electrical energy (current and voltage) for recharging the battery system 120. The operation of the electrified vehicle 100 is controlled by a controller or control system 124.

This control of the electrified vehicle 100 primarily includes controlling the electrified powertrain 108 to generate a desired amount of drive torque to satisfy a driver torque request provided via a driver interface 128 (e.g., an accelerator pedal). While a single controller or control system 124 is shown, it will be appreciated that the electrified vehicle 100 likely includes a plurality of different controllers or control modules (e.g., a battery pack control module, or BPCM) arranged in a desired control architecture and connected via a controller area network (CAN). The control system 124 is also configured to receive measurements from a set of sensors 132 that are configured to monitor various operating parameters of the electrified powertrain 108, including, but not limited to, speeds, torques, temperatures, pressures, and electrical parameters (voltages, currents, etc.). In one exemplary implementation, the control system 124 and the set of sensor(s) 132 collectively form the SOP estimation system 104 of the present application and thus are configured to perform the various functionalities, including the LSTM model and binary search for SOP estimation, described herein and in greater detail below.

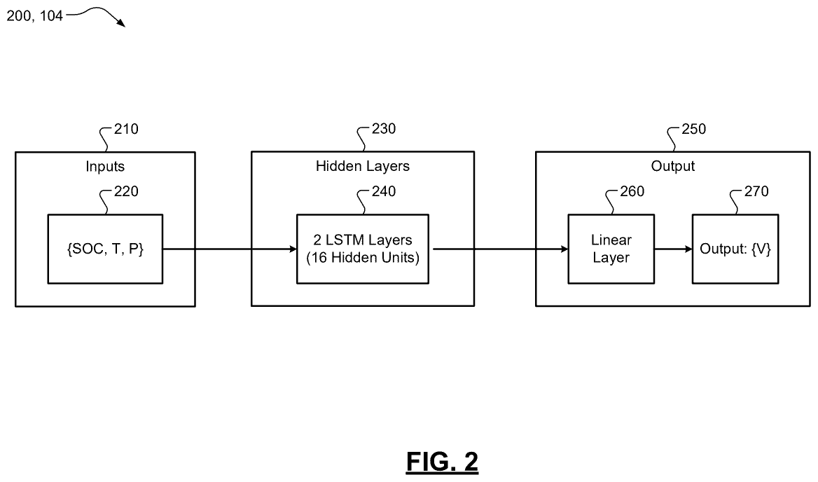

Referring now to FIG. 2, a functional block diagram of an example architecture 200 for the battery SOP estimation system 104 of FIG. 1 according to the principles of the present application is illustrated. Given the similarity between the process for calculating SOP for charging and discharging, only the discharge SOP case is described herein for the sake of conciseness and simplicity, but the techniques are applicable to both charging and discharging cases. The LSTM model is a recurrent neural network model, which has been shown to achieve better accuracy than ECM and electrochemical battery voltage estimation models. The example architecture 200 illustrates one exemplary implementation of the LSTM-based battery voltage estimation model, comprising 2 LSTM layers 230, 240, each equipped with 16 hidden units. The inputs 210 in this example include state of charge (SOC), power (P), and temperature (T), collectively referenced as 220, and the output 250 includes a linear layer 260 and voltage (V), referenced as 270. It will be appreciated that this is merely one example configuration for the LSTM model 200 that the optimal inputs and number of LSTM layers and hidden units could differ depending on the specific battery dataset. Therefore, these hyperparameters serve as illustrative examples rather than fixed values. The training data used in this work are vehicle drive cycle test data, including, but not limited to, UDDS, US06, LA92, and HWFET drive cycles. In one exemplary implementation, the SOP measurement test data shown and discussed herein is conducted on a Samsung® 30T 21700 cylindrical cell battery with lithium nickel manganese cobalt oxide (Li-NMC) chemistry (e.g., rated at 3000 milli-amp-hours, or mAh, and 35 A). These tests are conducted at six different temperatures, ranging from −20° Celsius (C) to 40° C.

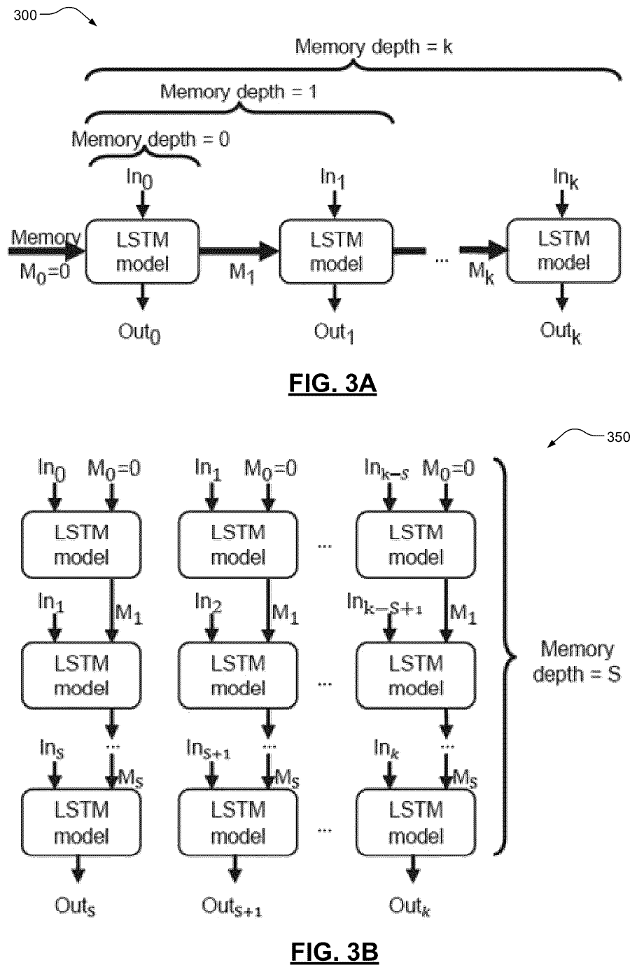

Referring now to FIGS. 3A-3B, example trainings 300, 350 of the LSTM model using continuous data and sequence data, respectively, according to the principles of the present application are illustrated. Viewing these example trainings 300, 350 side-by-side allows for comparison of an LSTM model trained with continuous data and with sequence data (i.e., data with fixed memory depth). Sequence training, in particular, significantly improves the performance of the proposed SOP estimation algorithm. In FIG. 3A, the training 300 of an LSTM model using a full batch of continuous data is shown, where LSTM memory captures past information by running through the entire dataset. The depth of LSTM memory will accumulate as the LSTM model advances to the subsequent time steps. The entire training dataset needs to be time-series consistent and clean to ensure that the LSTM model can gain the ability to refine and pass information related to voltage properly. In FIG. 3B, on the other hand, the training 350 of an LSTM using sequences is shown.

In contrast to training 300 with the entire continuous dataset (FIG. 3A), this training 350 feeds a fixed window (sequence) of prior data (e.g., 100 seconds) into the LSTM at each time step to initialize the memory states properly and then only uses the output at the current time step. With this training strategy, the LSTM just requires the prior data sequence to be continuous; therefore, each training point is isolated from others. Sequence training (e.g., training 350) opens up various machine learning techniques that cannot be conducted with continuous training (e.g., training 300), including data shuffling and mini-batch training. Thus, it enables LSTM to be trained from a discontinuous dataset. Considering inconsistency and outliers commonly existing in the dataset, sequence training significantly improves the accuracy of the LSTM-based voltage estimation model compared to continuous training. Furthermore, sequence training allows the LSTM to just be trained only on portions of the training data, such as the highest power portions, improving the accuracy under the conditions that are most important for the accuracy of the SOP estimator.

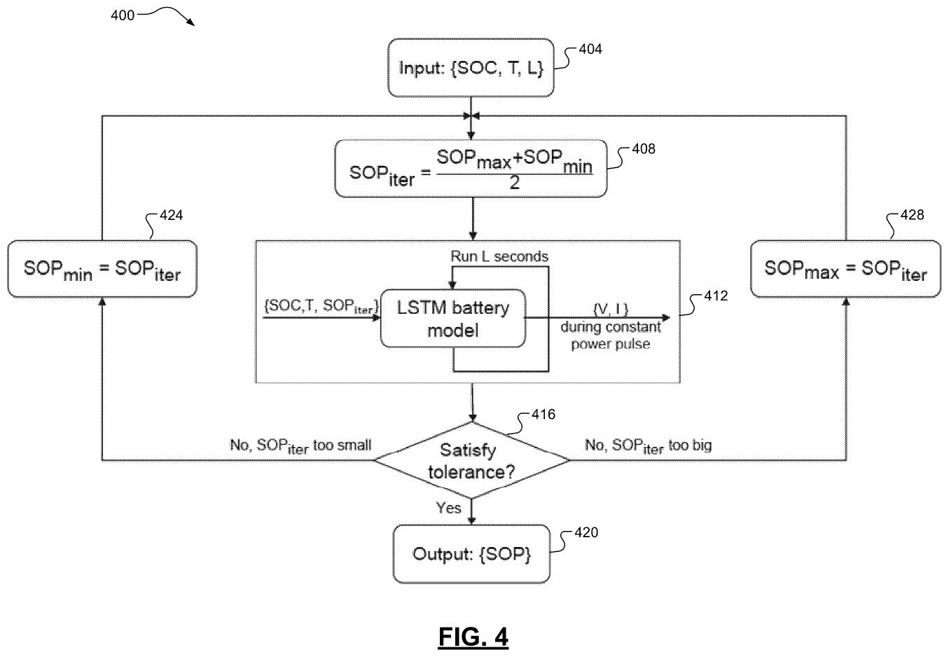

Referring now to FIG. 4, a flow diagram of an example SOP estimation method 400 for an electrified vehicle including a binary search process according to the principles of the present application is illustrated. The method 400 begins at 404 with inputs including SOC, T, and a power pulse length (L). For each iteration, the virtual power command SOPᵢₜₑᵣ is applied as a constant power pulse of L length (e.g., 10 seconds) to the LSTM battery model. At 408, the first iteration SOPᵢₜₑᵣ value is calculated from the initial SOPₘₐₓ and SOPₘᵢₙ values, where for the discharge case SOPₘₐₓ is a negative value which is slightly greater than the maximum possible discharge power (e.g. −200 watts (W), if maximum possible discharge power is −195 W). For the discharge case, SOPₘₐₓ can also be calculated as the product of the maximum discharge current and the maximum voltage (e.g., 50 A*4.2V=−210 W) since there is no way the discharge power can exceed this value. The SOPₘᵢₙ value for the discharge case is 0 W because a positive power is defined as charging.

At 412, the LSTM battery model then estimates battery voltage and current response based on the SOC, temperature, and SOPᵢₜₑᵣ inputs. At 416, the “Satisfy Tolerance” logical judgment block then compares the estimated voltage and current at the last time step of the pulse with the preset voltage and current limits. If the difference between the estimated voltage and current and the corresponding limits is within the error tolerance, then the method 400 proceeds to 428 where SOPᵢₜₑᵣ will be output as the final SOP estimate for the corresponding SOC and temperature level and the method 400 ends. Otherwise, if the SOPᵢₜₑᵣ is too small (i.e., the estimated current is smaller than limit, or the estimated voltage is higher than limit), the method 400 proceeds to 424 where the minimum power SOPₘᵢₙ will be updated to SOPᵢₜₑᵣ, and the new higher SOPᵢₜₑᵣ value will be recalculated using the binary search method 400. The same logic applies if the SOP exceeds a certain limit (see step 428). This iterative search process terminates only when an SOP value that satisfies the error tolerances is achieved at 416 and the value of SOPᵢₜₑᵣ is finally output.

Referring now to FIG. 5, example iterations 500 of the binary search process of for the example SOP estimation method 400 of FIG. 4 according to the principles of the present application are illustrated. As previously mentioned, while binary search is specifically described herein, it will be appreciated that other search algorithms could be utilized (e.g., other iterative search techniques). In this scenario, the SOP is constrained by a minimum voltage threshold, denoted as Vₘᵢₙ, therefore only voltage response to the constant power pulses are presented. In the first iteration, a −100 W initial constant power pulse is applied to the LSTM battery model, and the modeled voltage falls below the minimum limit. SOPᵢₜₑᵣ is therefore too big, so SOPₘₐₓ is set to −100 W and the next SOPᵢₜₑᵣ value is calculated as −100 W plus 0 W divided by two equals −50 W. This SOPᵢₜₑᵣ power command of −50 W is then applied to the model in the second iteration, and the process is repeated. After the six iterations 500, the voltage response narrows down to within an error tolerance of 0.005V from the voltage limit at the final time step of the power pulse. Consequently, the search process is terminated, and the algorithm outputs an estimated SOP value of −84.375 W.

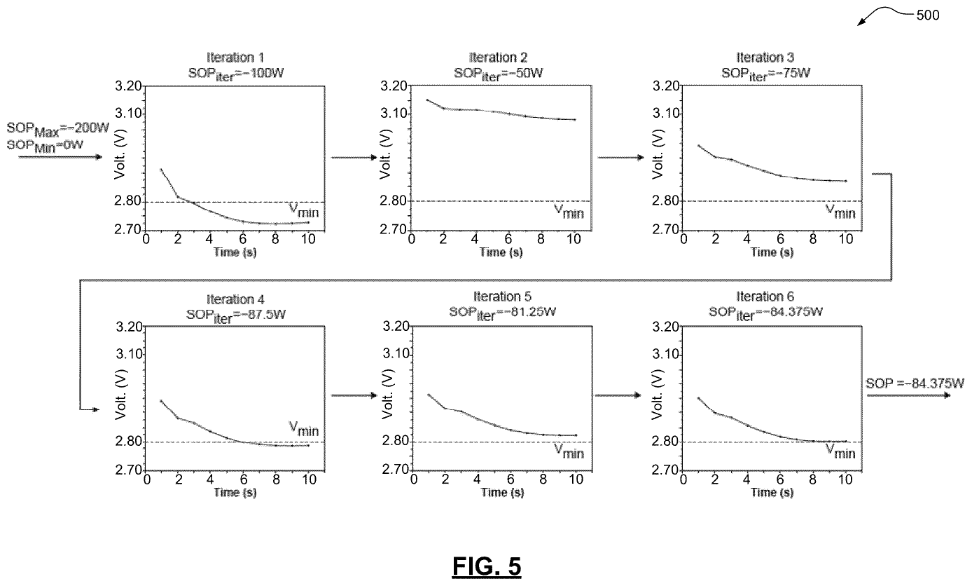

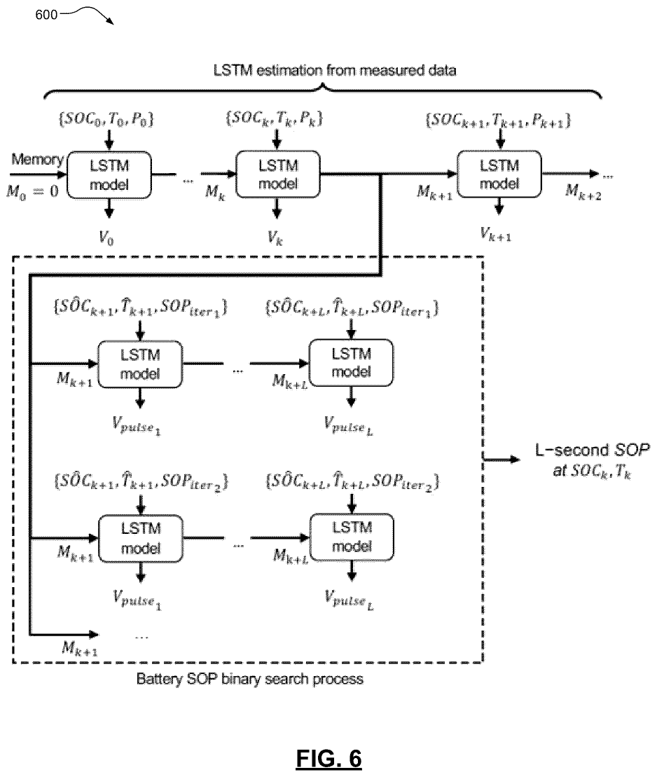

Referring now to FIG. 6, example LSTM model data and state flow 600 during an example SOP estimation process according to the principles of the present application is illustrated. While estimating SOP in a real-time application, the LSTM model estimates battery voltage from measured data (i.e., SOC, temperature, and power) at each time step in order to capture the battery's operational history in the LSTM memory states. Whenever battery power capability calculation is required (i.e., time step k in FIG. 6), the SOP binary search process is then conducted on the LSTM model with the present memory states (as indicated by Mk+1 in the example). The LSTM memory is reset to the Mk+1 state after estimating each constant power pulse response during the SOP binary search process. After power capability calculation, the LSTM model resumes tracking battery voltage based on the measured data. It is important to note that the power pulses applied are virtual and do not directly affect the battery, so the updated memory states during the SOP binary search process are discarded. The constant power pulse length L is a predefined value according to the user's input (e.g., 2, 10, 30 seconds). To further increase the accuracy of the predicted SOP pulse responses, the SOC value at each time step during the power pulse can be calculated as SOCₖ₊₁˜SOC_{k+L} according to the capacity depletion during the constant power pulse. Meanwhile, a battery thermal model can be applied to calculate battery temperature as Tₖ₊₁˜T_{k+L} considering the heat generated from the constant power pulse.

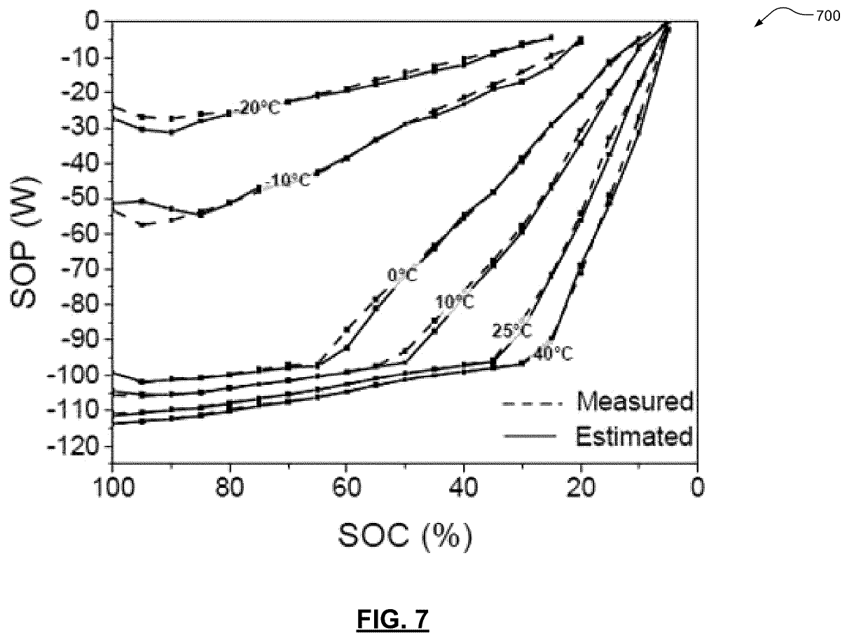

Referring now to FIG. 7, a plot 700 showing a comparison between estimated and measured ten-second discharging SOP at six different temperatures according to the principles of the present application is illustrated. As noted before, this test data is for a Samsung® 30T 21700 NMC cylindrical battery cell. These results prove that the proposed SOP estimation algorithm performs excellently, even at low temperatures and low SOC conditions where the battery has significant nonlinear characteristics, which are difficult to capture with conventional equivalent circuit based approaches to determining SOP.

It has also been discovered that using model that is only trained on a new battery system does not perform well for SOP estimation, particularly in the case of the above-described machine learning based SOP estimation model. Specifically, batteries age over time, causing their power capability to degrade significantly due to increased internal resistance. Not all batteries, even when they are the same type, age the same, as they can experience different conditions (usage patterns, ambient temperatures, etc.). Not all newly manufactured battery cells are the same either and have variance in capacity and resistance between cells. If the SOP estimation model is not retrained/updated to match the current characteristics of the individual cell, it could result in inaccurate SOP estimation thereafter. As previously discussed herein, SOP is a metric that is defined as the maximum amount of power that they battery system can absorb or provide for a specific length of time, which makes SOP a critical parameter, particularly for high power electrified vehicle applications. Overestimation of the SOP could result in a system malfunction due to safe operating limits being exceeded and, in extreme cases, could potentially result in reduced battery life, thermal runaway, and/or damage (e.g., overloading) and thereby increased replacement or warranty costs. Underestimation of the SOP could result in unnecessarily limiting of the battery output power and negatively impacted performance (vehicle response, vehicle range, etc.).

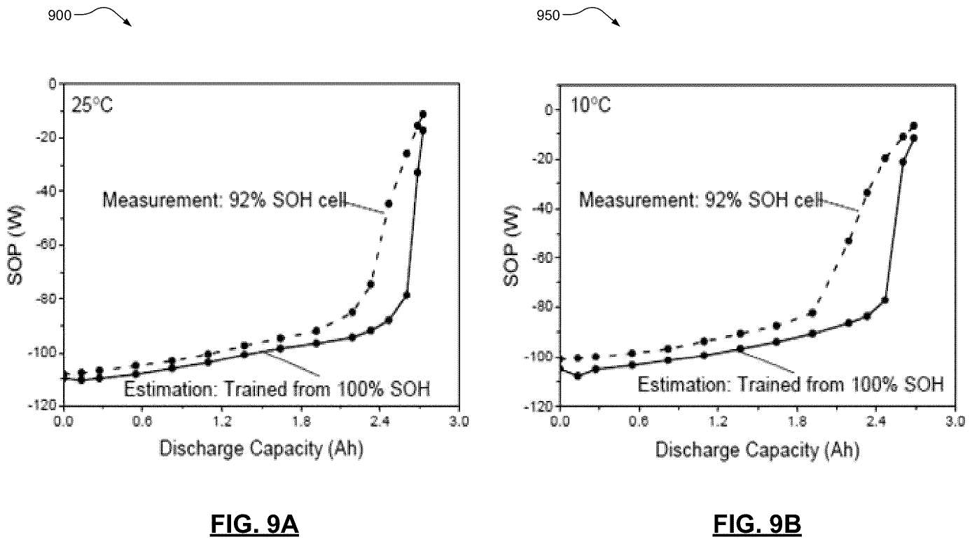

Referring now to FIGS. 9A-9B, SOP estimation techniques, including the specific machine learning model based technique discussed above, begin to encounter significant errors at ˜92% state of health (SOH) as shown in plots 900 and 950 for temperatures of 25 degrees Celsius (° C.) and 10° C., respectively. Even at the beginning of the battery system's life, the SOP estimation model may be inaccurate and ineffective for outlier battery cells in the same way it is inaccurate for aged cells. Conventional solutions to this problem utilize equivalent circuit-based models (ECMs) for SOP estimation, which do not inherently account for battery aging effects. To address this, a simple conventional solution is to increase the resistance values in the ECMs, as resistance typically increases with battery aging. Real-time updating, such as via an adaptive extended Kalman filter (AEKF), have been proposed to update the parameters of the ECMs in real-time. In another conventional solution, a fuzzy logic controller could be employed to dynamically adjust the estimated SOP. While these conventional techniques do fit a model to measured cell data, they typically have poor accuracy since the ECMs cannot capture all the complex non-linear characteristics of batteries and since they depend purely on measured data and cannot accurately extrapolate to SOC or temperature values beyond where the battery system has recently operated.

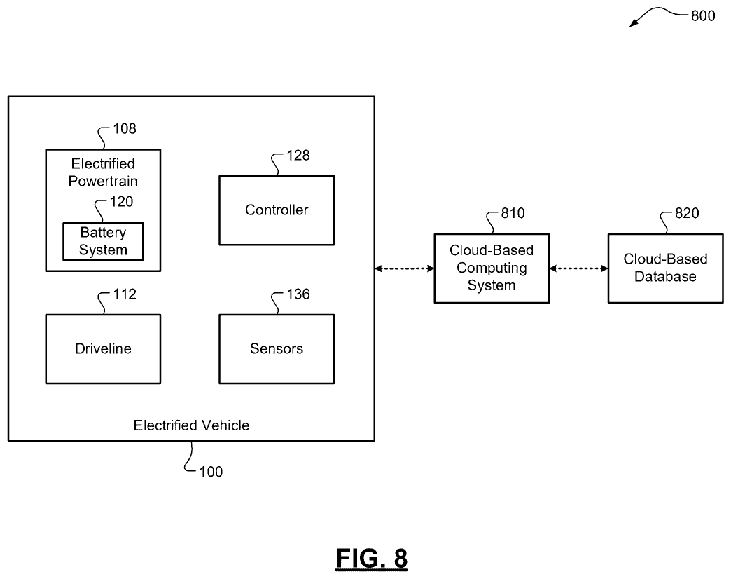

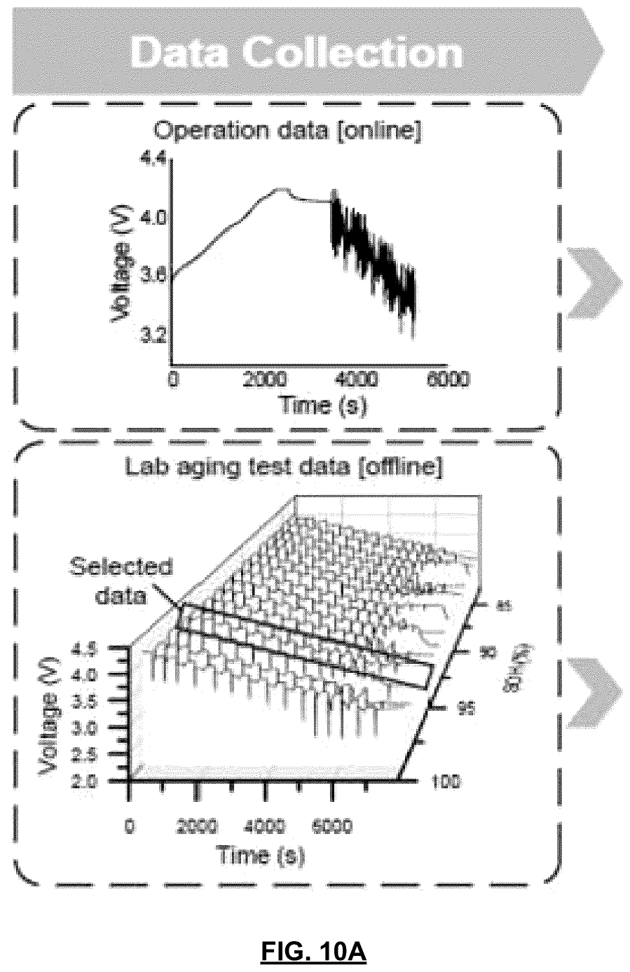

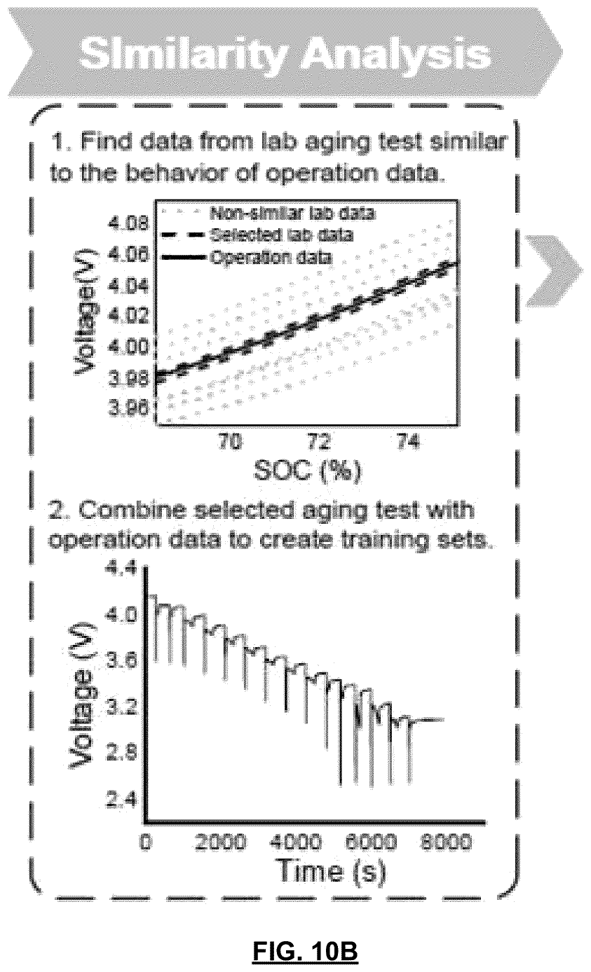

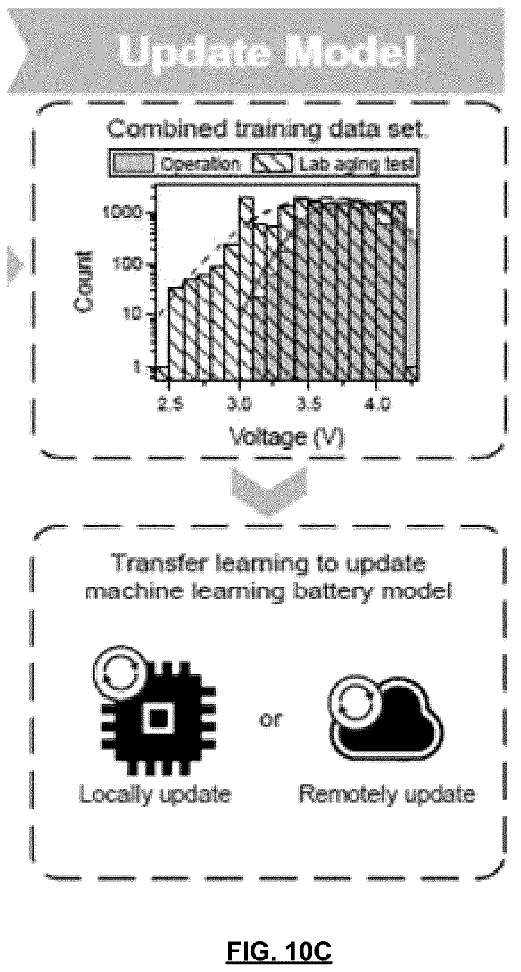

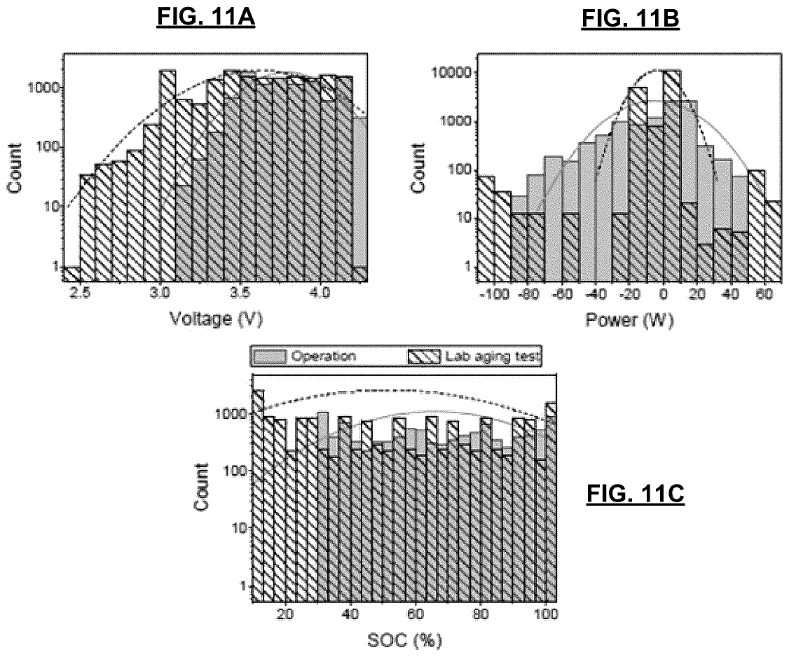

Many applications, including electrified vehicles, may typically only operate in a relatively narrow SOC or temperature range and thus may rarely approach peak power values (see FIGS. 11A-11C), resulting in real-time operation datasets being insufficient alone to update battery models. Battery lab data, in contrast to real-time or online (local) battery operation data, is another potential source for retraining/updating an SOP estimation model. The term “lab data” as used herein refers to a database of test data that is gathered by operating/testing the battery system in a controlled laboratory environment at varying temperatures, SOCs, and the like. Accordingly, in another aspect of the present application, techniques for updating a machine learning SOP estimation model for a battery system of an electrified vehicle are presented. These techniques utilize a combination of real-time (online) battery operation data with more comprehensive lab data to ensure the SOP estimation model is retrained/updated on a wide-range of operational conditions. FIG. 8 illustrates a functional block diagram of an example update system 800 for a trained SOP estimation model for a battery system 120 of an electrified vehicle 100. As shown, the update system 800 comprises a computing system (the controller 128, a separate or external computing system 810, or some combination thereof) that has access to lab data stored in a remote lab database 820, which could be generated and maintained by a supplier or manufacturer of the battery system 120. In some implementations, the lab data (or a portion thereof) may also be stored locally for updating the model as shown in FIG. 10C.

Initially, operation data is collected locally (at the electrified vehicle) as shown in FIG. 10A. After collecting this battery operation data, it can be utilized to identify and retrieve a subset of the lab data (e.g., from the cloud, or a remote server) as also shown in FIG. 10A. This subset of the lab data is the most relevant lab data for the current battery operation data. The combination of the online operation data and only the subset of the lab data ensures training/updating based on wide range of operational conditions and enables the SOP estimation model to account for cell-specific behaviors (see FIG. 10B). Next, as shown in FIG. 10C, transfer learning is performed, which refers to updating a machine learning model while keeping at least some of the original model characteristics. This can include applying a smaller learning rate or ratio (LR) for the retraining/updating process. The transfer learning process could be performed locally, remotely (in the cloud), or via some combination thereof. Potential benefits include a more accurate battery SOP estimation over time (as the battery system ages) and, in turn, improved battery charging/discharging control and performance.

To summarize, a novel framework for enhancing the accuracy and robustness of SOP estimation machine-learning algorithms or models by integrating battery operation data with lab data. The proposed technique addresses the limitation of traditional approaches, which rely heavily on predefined parameters and are prone to inaccuracies due to cell aging and variation. As shown in FIGS. 9A-9C, the workflow of the proposed invention can be summarized as three steps: (1) Data Collection—a combining both battery operation data with comprehensive lab data to ensure model being updated on a wide range of operational conditions; (2) Similarity Analysis—identifying the most relevant lab data based on similarity to battery operation data, enabling the model the account for cell-specific behaviors; and (3) Model Updating—using transfer learning techniques to update the machine learning-based battery model, ensuring it adapts to the current state of the battery while retaining general battery behavior.

The first step (1) of this workflow is Data Collection. In one exemplary embodiment, the accuracy of the SOP estimation model relies on the accuracy of the LSTM based battery model. To ensure that the SOP estimation model remains effective against cell degradation and cell-to-cell variation, the LSTM model can be continuously updated to adapt to the aged battery's physical behavior. In real-life applications, real-time operation data for the battery system can be collected during deployment and can then be used to re-train the LSTM model. As discussed above, electrified vehicles may typically only operate in a relatively narrow SOC or temperature range and may rarely approach peak power values, resulting in real-time operation data that is not wholly sufficient to retrain the SOP estimation model. In other words, the real-time datasets would not typically cover the whole operating space of the battery system like comprehensive tests performed in a lab environment (i.e., the lab data). To illustrate this, FIGS. 11A-11C show Operation Data, which is representative of real-time operation data of the battery system, with comprehensive Lab Data.

As shown, compared to the lab data, the real-time operation data occurs within a relatively narrow voltage range of 3.0V to 4.2V and an SOC range of 30% to 100%. Therefore, if the real-time operation data were used on its own to retrain or update the SOP estimation model, the updated SOP estimation model would not capture the full SOC and voltage range of the cell and would therefore be unable to estimate SOP over the full operating space of the vehicle battery system. Therefore, in addition to the battery operation data collected from an electrified vehicle for example, aging test data which includes high power pulses and the full SOC range is also collected offline in a laboratory environment. One example of the aging test profile can involve (i) a 0.5 C-rate standard charge, (ii) characterization tests (capacity/HPPC/SOP), (iii) a 1 C-rate charge with a 1 A cut-off current, and both (iv) a 6 C-rate constant current discharge to 5% SOC (for a first cell) and (v) a US06 profile (˜1 C-rate) discharge to 5% SOC (for a second cell), which can be repeated ˜100 times. The lab aging test must cover a wide range of battery operations (e.g., temperature, power, voltage, and SOC) at different SOH levels to achieve the best accuracy over the lifetime of the electrified vehicle.

The second step (2) of this workflow is Similarity Analysis. This analysis involves determining or identifying a subset or portion of the lab data that is most similar or relevant to the operation data. The phrases “most similar” and “most relevant” refer to a subset or portion of the lab data having respective parameters that are the most similar to the real-time operation data (temperature, voltage, SOH, etc.). For example, given the aging test data with various SOH levels, the next step is identifying the one among these profiles with the most similar operational behavior to the target cell. Using the selected lab data (also referred to as aging test data herein) and the battery operation data, the battery model can be updated in the following third step (discussed in greater detail below) utilizing the information contained within the combined data. There are various ways to perform the similarity analysis considering data availability and applications. As previously discussed, in one exemplary embodiment, the aging test profile includes two cells aged from different profiles (one with 6 C-rate constant current ‘CC’ and one with US06 drive cycle ‘US06’). These two aging profiles have identical characterization tests and 1 C-rate charge with a 1 A cut-off current step.

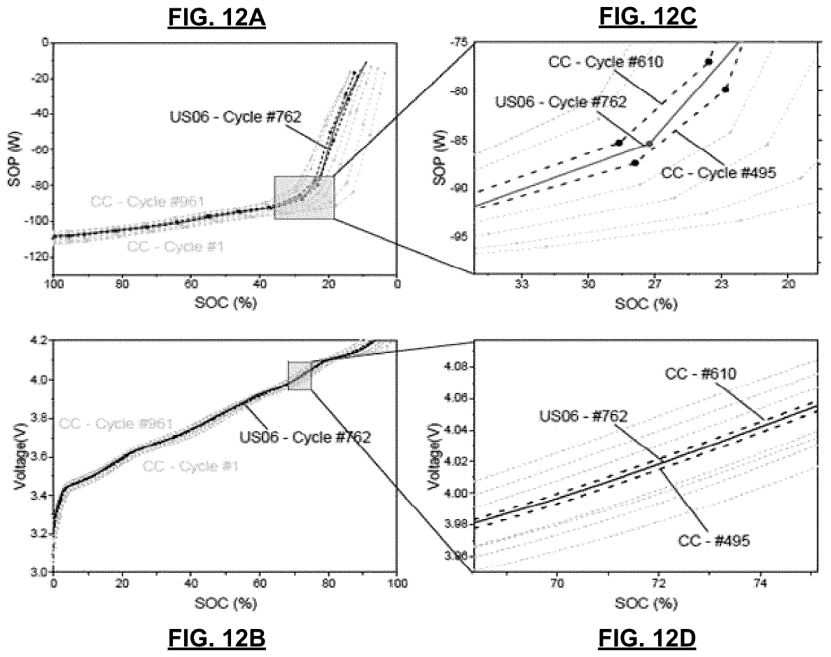

In FIGS. 12A-12D, an experiment exploring the relationship between battery SOP behavior and 1 C-rate charge behavior is shown. The ‘US06’ cell is assumed to be the real-time operation cell (the target cell), while the ‘CC’ cell is used to provide aging test data offline. When looking into the SOP versus SOC plot in FIGS. 11A-11D, it shows that when the ‘US06’ cell is aged with 762 aging cycles, its SOP versus SOC curve fell between the ‘CC’ cell's 619 and 495 aging cycle curves. Then, by checking the 1 C-rate charge profile plot in FIG. 12B, it is clear that the ‘US06’ cell after 762 aging cycles has a voltage versus SOC curve that again falls between the ‘CC’ cell's 619 and 495 aging cycle curves. This is because battery internal resistance highly determines both battery SOP and charge voltage behaviors. These results demonstrate the feasibility of selecting lab data with the most similar SOP behavior to the target cell by identifying similar battery charge voltage behavior. This is significant because characterization tests, including SOP tests, are unavailable during real-time operation; however, battery charge profiles are available. In summary, one can select data from the lab aging tests with similar SOP behaviors to the target cell, by performing similarity analysis on batteries'charge voltage behavior.

The third (3) and final step of the workflow is Model Updating. After completing the previous two steps (1)-(2), the SOP estimation model is updated using a combination of the real-time operation data and the subset of the lab data that best matches the current properties of the battery system (a combined dataset). This combined dataset contains information on how the target cell behaves under a wide range of conditions and considers the current characteristics of the battery cell. The SOP estimation model can either be updated locally or remotely, or in some combination thereof. In a local update, both lab aging data and battery operation data are stored within the BMS to retrain the battery model. In a remote update, battery operation data are transmitted to a cloud server, where they are combined with lab aging data to retrain the battery model. The updated model is then sent back and deployed to the BMS. Since a machine learning based battery model (LSTM) is used in the SOP estimation algorithm, the model is updated via transfer learning, a method of updating a machine learning model while keeping some of the original model characteristics. The following describes one example of how the SOP estimation model is updated.

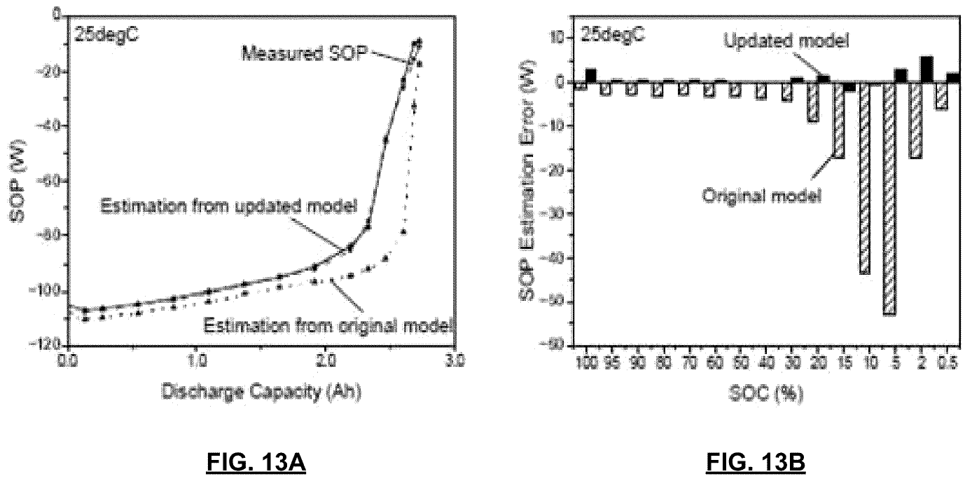

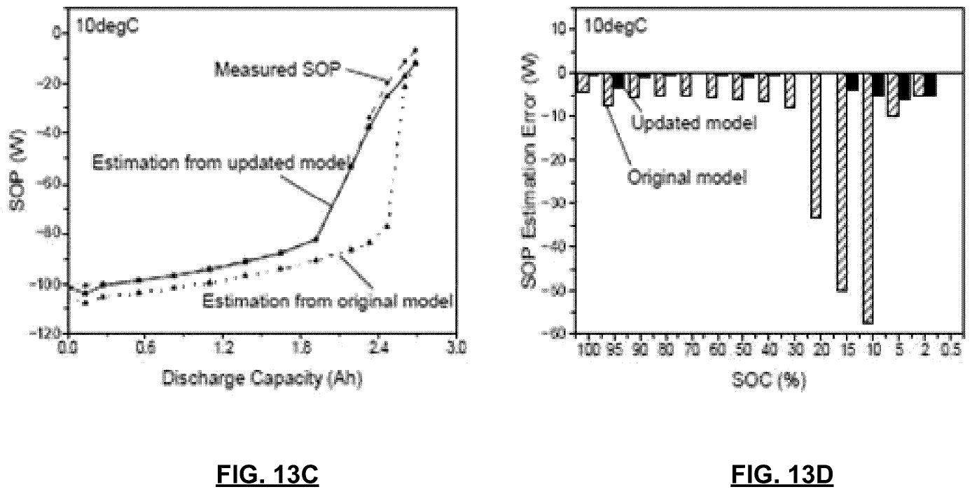

After preparing the re-training data, data were randomized and split into 70% for training and 30% for validation. Then, the LSTM based battery model was updated by a machine learning training process (e.g., gradient decent). Notably, during the re-training process, a smaller initial learning rate (LR) was chosen (LR=0.0001 for training the original model and LR=0.00001 for updating the model). A relatively lower learning rate is essential for this model update process to ensure transfer learning takes place. If the learning rate is too large, it can cause the LSTM model's trainable parameters to be updated excessively, leading to overfitting on the prepared data and a loss of general battery behavior. Our goal is to let the model learn the changes due to aging and cell-to-cell variation from the prepared data while retaining the general behavior of the battery learned from the initial comprehensive data. FIGS. 13A-13D compare the SOP estimation accuracy between the original and updated models, validated using 10-second pulse SOP measurement results from a 21700 cylindrical NMC chemistry cell at 10° C. and 25° C. The original model, trained on data from a 100% SOH cell, shows a maximum SOP estimation error of 57W for a 92% SOH cell at 10% SOC and 10° C. In contrast, after applying our proposed update technique, the updated model significantly improves SOP estimation accuracy, with a maximum error of only 6W in all cases, an 89% reduction of error.

In summary, the most unique part of the proposed technique is its ability to integrate battery operation and lab aging test data to update the battery model. This contrasts with existing approaches which predominantly rely solely on battery operation data to update their models. Without incorporating lab data, it is unlikely that the battery model can fully learn the variations in operational behavior due to aging across a full range of conditions. The proposed novel approach significantly enhances the accuracy of the battery model across a wide operational range by also using lab aging data, thereby ensuring the effectiveness of the SOP estimation algorithm despite the impacts of cell aging and cell-to-cell variation. The second contribution is the application of transfer learning techniques in battery modeling. In other studies, updating a battery model typically involves completely re-training or re-optimizing it using comprehensive data. In contrast, transfer learning allows the model to be updated using a specially designed small dataset (e.g., battery behavior variations due to aging), while retaining most of the learned knowledge from the original model. This technique significantly conserves resources, including time, computation, and data.

According to one aspect of the invention, an update system for a trained SOP estimation model for a battery system of an electrified vehicle is presented. In one exemplary implementation, the update system comprises a database configured to store lab data including test data of the battery system across a plurality of different operation conditions and a computing system configured to obtain real-time operation data of the battery system while deployed in the electrified vehicle, access the trained SOP estimation model, wherein the trained SOP estimation model is a machine learning model that is configured to estimate a SOP of the battery system based on a set of input parameters, identify and obtain, from the database, a subset of the lab data that is most relevant to the real-time operation data of the battery system, update the SOP estimation model via a low learning rate transfer learning process and using at least the subset of the lab data to obtain an updated SOP estimation model, and output the updated SOP estimation model.

In some implementations, the computing system is further configured to generate a combined training dataset including the real-time operation data and the subset of the lab data and to update the SOP estimation model using the combined training dataset. In some implementations, the database is a cloud-based database, wherein the computing system includes at least one of a controller of the electrified vehicle and a cloud-based computing system, and wherein the controller is configured to store and utilize the updated SOP estimation model. In some implementations, the lab data includes, for each of a plurality of different temperatures, battery cell voltage and SOH over time. In some implementations, the lab data is generated by a supplier or manufacturer of the battery system. In some implementations, the low learning rate transfer learning process involves a learning rate that is smaller than a learning rate of the initial training of the trained SOP estimation model.

In some implementations, the learning rate of the low learning rate transfer learning process is of approximately 0.00001, and wherein the learning rate of the initial training of the trained SOP estimation model approximately 0.0001. In some implementations, the trained SOP estimation model is an LSTM based recurrent neural network model. In some implementations, the controller is configured to utilize the updated SOP estimation model by (i) estimating a voltage of the battery system based on the set of input parameters including at least SOC, temperature, and power or current, and (ii) performing a binary search process to determine a final estimated SOP that causes an estimated parameter of the battery system to fall within a desired range at a final time step of a power pulse. In some implementations, the updated SOP estimation model includes a battery voltage estimation model trained using a sequence training process.

According to another aspect of the invention, an update method for a trained SOP estimation model for a battery system of an electrified vehicle is presented. In one exemplary implementation, the update method comprises obtaining, by a computing system, real-time operation data of the battery system while deployed in the electrified vehicle, accessing, by the computing system, the trained SOP estimation model, wherein the trained SOP estimation model is a machine learning model that is configured to estimate a SOP of the battery system based on a set of input parameters, identifying and obtaining, by the computing system and from a database, a subset of lab data that is most relevant to the real-time operation data of the battery system, wherein the database is configured to store the lab data including test data of the battery system across a plurality of different operation conditions, updating, by the computing system, the SOP estimation model via a low learning rate transfer learning process and using at least the subset of the lab data to obtain an updated SOP estimation model, and outputting, by the computing system, the updated SOP estimation model.

In some implementations, the update method further comprises generating, by the computing system, a combined training dataset including the real-time operation data and the subset of the lab data, wherein the updating, by the computing system, of the SOP estimation model is performed using the combined training dataset. In some implementations, the database is a cloud-based database, wherein the computing system includes at least one of a controller of the electrified vehicle and a cloud-based computing system, and wherein the controller is configured to store and utilize the updated SOP estimation model. In some implementations, the lab data includes, for each of a plurality of different temperatures, battery cell voltage and SOH over time. In some implementations, the lab data is generated by a supplier or manufacturer of the battery system. In some implementations, the low learning rate transfer learning process involves a learning rate that is smaller than a learning rate of the initial training of the trained SOP estimation model.

In some implementations, the learning rate of the low learning rate transfer learning process is of approximately 0.00001, and wherein the learning rate of the initial training of the trained SOP estimation model approximately 0.0001. In some implementations, the trained SOP estimation model is an LSTM based recurrent neural network model. In some implementations, the update method further comprises utilizing, by the controller, the updated SOP estimation model by (i) estimating a voltage of the battery system based on the set of input parameters including at least state of charge (SOC), temperature, and power or current, and (ii) performing a binary search process to determine a final estimated SOP that causes an estimated parameter of the battery system to fall within a desired range at a final time step of a power pulse. In some implementations, the updated SOP estimation model includes a battery voltage estimation model trained using a sequence training process.

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. An update system for a trained state of power (SOP) estimation model for a battery system of an electrified vehicle, the update system comprising:
a database configured to store lab data including test data of the battery system across a plurality of different operation conditions; and
a computing system configured to:
obtain real-time operation data of the battery system while deployed in the electrified vehicle;
access the trained SOP estimation model, wherein the trained SOP estimation model is a machine learning model that is configured to estimate a SOP of the battery system based on a set of input parameters;
identify and obtain, from the database, a subset of the lab data that is most relevant to the real-time operation data of the battery system;
update the SOP estimation model via a low learning rate transfer learning process and using at least the subset of the lab data to obtain an updated SOP estimation model; and
output the updated SOP estimation model.

2. The update system of claim 1, wherein the computing system is further configured to generate a combined training dataset including the real-time operation data and the subset of the lab data and to update the SOP estimation model using the combined training dataset.

3. The update system of claim 2, wherein the database is a cloud-based database, wherein the computing system includes at least one of a controller of the electrified vehicle and a cloud-based computing system, and wherein the controller is configured to store and utilize the updated SOP estimation model.

4. The update system of claim 3, wherein the lab data includes, for each of a plurality of different temperatures, battery cell voltage and state of health (SOH) over time.

5. The update system of claim 4, wherein the lab data is generated by a supplier or manufacturer of the battery system.

6. The update system of claim 4, wherein the low learning rate transfer learning process involves a learning rate that is smaller than a learning rate of the initial training of the trained SOP estimation model.

7. The update system of claim 6, wherein the learning rate of the low learning rate transfer learning process is of approximately 0.00001, and wherein the learning rate of the initial training of the trained SOP estimation model approximately 0.0001.

8. The update system of claim 2, wherein the trained SOP estimation model is a long short-term memory (LSTM) based recurrent neural network model.

9. The update system of claim 8, wherein the controller is configured to utilize the updated SOP estimation model by:
(i) estimating a voltage of the battery system based on the set of input parameters including at least state of charge (SOC), temperature, and power or current; and
(ii) performing a binary search process to determine a final estimated SOP that causes an estimated parameter of the battery system to fall within a desired range at a final time step of a power pulse.

10. The update system of claim 9, wherein the updated SOP estimation model includes a battery voltage estimation model trained using a sequence training process.

11. An update method for a trained state of power (SOP) estimation model for a battery system of an electrified vehicle, the update method comprising:
obtaining, by a computing system, real-time operation data of the battery system while deployed in the electrified vehicle;
accessing, by the computing system, the trained SOP estimation model, wherein the trained SOP estimation model is a machine learning model that is configured to estimate a SOP of the battery system based on a set of input parameters;
identifying and obtaining, by the computing system and from a database, a subset of lab data that is most relevant to the real-time operation data of the battery system, wherein the database is configured to store the lab data including test data of the battery system across a plurality of different operation conditions;
updating, by the computing system, the SOP estimation model via a low learning rate transfer learning process and using at least the subset of the lab data to obtain an updated SOP estimation model; and
outputting, by the computing system, the updated SOP estimation model.

12. The update method of claim 11, further comprising generating, by the computing system, a combined training dataset including the real-time operation data and the subset of the lab data, wherein the updating, by the computing system, of the SOP estimation model is performed using the combined training dataset.

13. The update method of claim 12, wherein the database is a cloud-based database, wherein the computing system includes at least one of a controller of the electrified vehicle and a cloud-based computing system, and wherein the controller is configured to store and utilize the updated SOP estimation model.

14. The update method of claim 13, wherein the lab data includes, for each of a plurality of different temperatures, battery cell voltage and state of health (SOH) over time.

15. The update method of claim 14, wherein the lab data is generated by a supplier or manufacturer of the battery system.

16. The update method of claim 14, wherein the low learning rate transfer learning process involves a learning rate that is smaller than a learning rate of the initial training of the trained SOP estimation model.

17. The update method of claim 16, wherein the learning rate of the low learning rate transfer learning process is of approximately 0.00001, and wherein the learning rate of the initial training of the trained SOP estimation model approximately 0.0001.

18. The update method of claim 12, wherein the trained SOP estimation model is a long short-term memory (LSTM) based recurrent neural network model.

19. The update method of claim 18, further comprising utilizing, by the controller, the updated SOP estimation model by:
(i) estimating a voltage of the battery system based on the set of input parameters including at least state of charge (SOC), temperature, and power or current; and
(ii) performing a binary search process to determine a final estimated SOP that causes an estimated parameter of the battery system to fall within a desired range at a final time step of a power pulse.

20. The update method of claim 19, wherein the updated SOP estimation model includes a battery voltage estimation model trained using a sequence training process.
